(19) United States
(12) Patent Application Publication
(10) Pub. No.: US 2007/0199655 A1
(43) Pub. Date: Aug. 30, 2007

(54) SUBSTRATE PROCESSING APPARATUS, METHOD FOR MODIFYING SUBSTRATE PROCESSING CONDITIONS AND STORAGE MEDIUM

(75) Inventors: Takeshi Yokouchi, Miyagi-gun (JP); Fumiko Yagi, Miyagi-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/679,363

(22) Filed: Feb. 27, 2007

Related U.S. Application Data
(60) Provisional application No. 60/783,827, filed on Mar. 21, 2006.

(30) Foreign Application Priority Data
Feb. 28, 2006 (JP) 2006-053670

(51) Int. Cl. H01L 21/306

(52) U.S. Cl. 156/345.11

(57) ABSTRACT

A substrate processing apparatus includes a setting unit for setting substrate processing conditions for a substrate in a substrate processing unit for performing a process on the substrate; a detection unit for detecting an abnormality of the substrate processing unit while the substrate processing unit performs the process on the substrate under the substrate processing conditions; a stopping unit for stopping the process on the substrate of the substrate processing unit if the abnormality is detected; and a modifying unit for modifying the substrate processing conditions for a substrate on which the process is stopped to be performed by the stopping unit. Further, a method for modifying substrate processing conditions includes the steps of setting processing conditions; detecting an abnormality of the substrate processing unit; stopping the process if the abnormality is detected; and modifying the processing conditions for a substrate on which the process is stopped.

### FIELD OF THE INVENTION

The present invention relates to a substrate processing apparatus, a method for modifying substrate processing conditions and a storage medium; and, more particularly, to a substrate processing apparatus, a method for modifying substrate processing conditions and a storage medium that serve to modify processing conditions for a substrate.

### BACKGROUND OF THE INVENTION

In a substrate processing apparatus for performing a process such as a plasma process on a wafer that serves as a substrate, processing conditions of the plasma process for the wafer are not usually changed while processing one wafer Furthermore, the processing conditions of the plasma process performed by the substrate processing apparatus are called a process recipe (hereinafter, simply referred to as a “recipe”), which is stored in a server or the like connected to the substrate processing apparatus.

The substrate processing apparatus includes a process unit for performing the plasma process on each wafer in a processing chamber; a loader unit for unloading wafers to transfer from a container that accommodates a plurality of wafers equivalent to one lot; and a load-lock unit for transmitting wafers between the loader unit and the process unit.

While such a substrate processing apparatus performs, e.g., the plasma process on the wafers, if errors such as breakdowns or process abnormalities occur in the process unit that performs the process, and thus the process on the wafer is stopped, a residual process recipe is created according to the remaining processing conditions for the wafer (hereinafter, referred to as an “unfinished wafer”). Thereafter, the process for the unfinished wafer is reperformed according to the residual process recipe (see, e.g., Japanese Patent Publication Application No. 2004-319961).

However, in the conventional substrate processing apparatus as described above, the residual process recipe is created according to the remaining processing conditions for the unfinished wafer at the time when the process of the wafer is stopped. Therefore, in some cases depending on the circumstances that caused the stoppage, the process on the unfinished wafer cannot be reperformed on the basis of the residual process recipe. In these cases, the unfinished wafer needs to be unloaded from the inside of the processing chamber.

### SUMMARY OF THE INVENTION

It is, therefore, an object of the present invention to provide a substrate processing apparatus, a method for modifying substrate processing conditions and a storage medium, for reperforming a process on a substrate whose process has been stopped in an optimal manner without unloading the substrate from an inside of a processing chamber.

In accordance with one aspect of the invention, there is provided a substrate processing apparatus, including a setting unit for setting substrate processing conditions for a substrate in a substrate processing unit for performing a process on the substrate; a detection unit for detecting an abnormality of the substrate processing unit while the substrate processing unit performs the process on the substrate under the substrate processing conditions; a stopping unit for stopping the process on the substrate of the substrate processing unit if the abnormality is detected; and a modifying unit for modifying the substrate processing conditions for a substrate on which the process is stopped to be performed by the stopping unit.

In accordance with another aspect of the invention, there is provided a method for modifying substrate processing conditions, including the steps of setting substrate processing conditions for a substrate in a substrate processing unit for performing a process on the substrate; detecting an abnormality of the substrate processing unit while the substrate processing unit performs the process on the substrate under the substrate processing conditions; stopping the process of the substrate processing unit on the substrate if the abnormality is detected; and modifying the substrate processing conditions for a substrate on which the process is stopped to be performed in the stopping step.

In accordance with still another aspect of the invention, there is provided a computer readable storage medium for storing therein a program executable on a computer, wherein the program includes a setting module for setting substrate processing conditions for a substrate in a substrate processing unit for performing a process on the substrate; a detection module for detecting an abnormality of the substrate processing unit while the substrate processing unit performs the process on the substrate under the substrate processing conditions; a stopping module for stopping the process of the substrate processing apparatus on the substrate if the abnormality is detected; and a modifying module for modifying the substrate processing conditions for a substrate on which the process is stopped to be performed by the stopping module.

In accordance with the apparatus, method and storage medium described above, the processing conditions for the substrate whose process has been stopped can be modified appropriately depending on the circumstances that caused the stoppage. Therefore, a process for the substrate whose process has been stopped can be reperformed in an optimal manner without unloading it from the inside of the processing chamber.

In the substrate processing apparatus, it is preferable that the modifying unit modifies the substrate processing conditions by revising the substrate processing conditions.

In the method for modifying processing conditions, it is preferable that, in the modifying step, the processing conditions are modified by revising the processing conditions.

In accordance with the apparatus and method described above, the processing conditions are modified by revising the processing conditions. Therefore, the processing conditions for the substrate whose process has been stopped can be modified appropriately depending on the circumstances that caused the stoppage.

In the substrate processing apparatus, it is preferable that the substrate processing conditions include a plurality of processing conditions, and the modifying unit modifies the substrate processing conditions by selecting one or more processing conditions among the plurality of processing conditions.

In the method for modifying processing conditions, it is preferable that the substrate processing conditions include a plurality of processing conditions, and, in the modifying step, the substrate processing conditions are modified by selecting one or more processing conditions among the plurality of the processing conditions.

In accordance with the apparatus and method described above, the processing conditions are modified by selecting specific processing conditions among a plurality of processing conditions. Therefore, the processing conditions for the substrate whose process has been stopped can be modified appropriately depending on the circumstances that caused the stoppage.

### BRIEF DESCRIPTION OF THE DRAWINGS

The above and other objects and features of the present invention will become apparent from the following description of embodiments, given in conjunction with the accompanying drawings, in which:

FIG. 1 is a plan view for schematically showing a configuration of a substrate processing apparatus in accordance with an embodiment of the present invention;

FIG. 2A is a cross sectional view of a second process unit of FIG. 1, which is taken along the line II-II of FIG. 1;

FIG. 2B is an enlarged view of a portion A in FIG. 2A;

FIG. 3 is a perspective view for schematically showing a configuration of a second process ship of FIG. 1;

FIG. 4 describes a schematic configuration of a system controller in the substrate processing apparatus of FIG. 1;

FIG. 5 a block diagram for showing a schematic configuration of a main part of an EC of FIG. 4;

FIG. 6 is a flow chart for explaining a sequence of a first substrate process performed by the substrate processing apparatus in accordance with an embodiment of the present invention;

FIGS. 7A and 7B show a recipe edit view shown in a display of an operation panel;

FIG. 8 is a flow chart for explaining a sequence of a second substrate process performed by the substrate processing apparatus in accordance with an embodiment of the present invention;

FIGS. 9A and 9B show a recipe edit view shown in the display of the operation panel;

FIGS. 10 and 11 are flow charts for explaining a sequence of a third substrate process performed by the substrate processing apparatus in accordance with an embodiment of the present invention;

FIGS. 12A and 12B shows a recipe edit view shown in the display of the operation panel;

FIG. 13 is a plan view for schematically showing a configuration of a substrate processing apparatus in accordance with a first modified example of the embodiment of the present invention; and

FIG. 14 is a plan view for schematically showing a configuration of a substrate processing apparatus in accordance with a second modified example of the embodiment of the present invention.

### DETAILED DESCRIPTION OF THE EMBODIMENTS

Hereinafter, embodiments of the present invention will be described in detail with reference to the accompanying drawings.

Firstly, a substrate processing apparatus in accordance with a first embodiment of the present invention will be discussed.

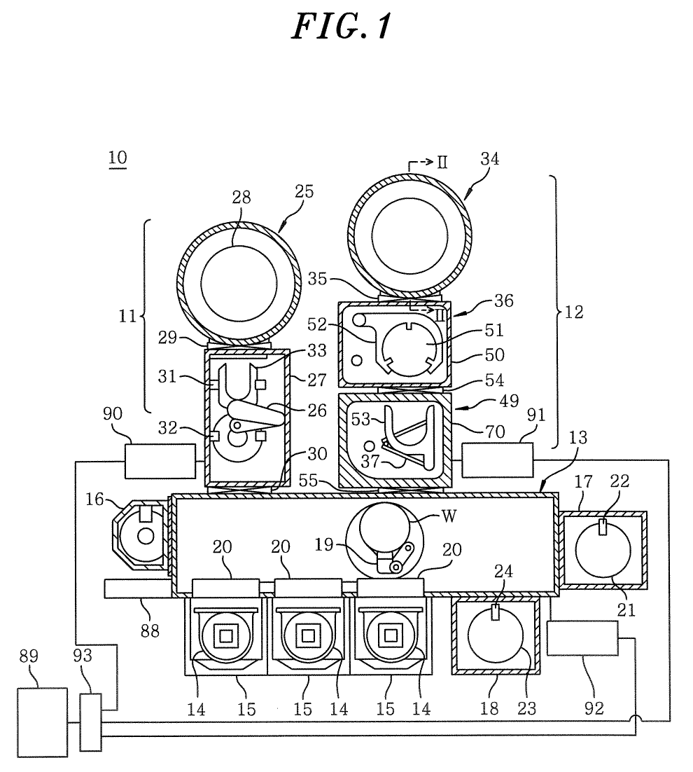

FIG. 1 is a plan view for schematically showing a configuration of a substrate processing apparatus in accordance with the first embodiment of the present invention.

As shown in FIG. 1, the substrate processing apparatus 10 includes a first process ship 11 for performing a reactive ion etching (hereinafter, referred to as “RIE”) on a wafer for an electronic device (a substrate; hereinafter, simply referred to as a “wafer”) W; a second process ship 12, which is disposed in parallel with the first process ship 11, for performing a COR (Chemical Oxide Removal) process and a PHT (Post Heat Treatment) process, which will be described below, on the wafer W that has undergone the RIE process in the first process ship 11; and a rectangular loader unit 13 that serves as a common transfer chamber connected to the first process ship 11 and the second process ship 12, respectively.

Herein, the COR process is a process in which an oxide film of a target object is chemically reacted with gas molecules to generate a product. Further, the PHT process is a process in which the COR processed target object is heated to remove the product, generated by the chemical reaction in the COR process, from the target object by vaporization and thermal oxidation. As mentioned above, the oxide film of the target object is removed by using neither plasma nor water in the COR and PHT processes, especially in the COR process. Therefore, the COR and PHT processes can be regarded as plasmaless and dry cleaning processes.

The loader unit 13 is connected to the first and the second process ship 11 and 12, three FOUP mounting tables 15, an orienter 16, and a first and a second IMS (Integrated Metrology System) 17 and 18. A FOUP (Front Opening Unified Pod) 14, which serves as a container for accommodating twenty-five wafers W equivalent to one lot, is mounted on each of the FOUP mounting tables 15. The orienter 16 performs a pre-alignment of the position of the wafer W unloaded from the FOUP 14, and the first and the second IMS 17 and 18, which is manufactured by, e.g., Therma-Wave, Inc., measures a surface state of the wafer W.

The first and the second process ship 11 and 12 are connected to a sidewall of the loader unit 13 arranged in a longitudinal direction thereof, and disposed to face the three FOUP mounting tables 15 across the loader unit 13. Further, the orienter 16 is disposed on one end portion in the longitudinal direction of the loader unit 13; the first IMS 17 is disposed on the other end portion in the longitudinal direction of the loader unit 13; and the second IMS 18 is disposed in line with the three FOUP mounting tables 15.

The loader unit 13 is provided with a dual scara arm type transfer arm unit 19 disposed therein for transferring the wafer W; and three loading ports 20 serving as input ports of the wafers, the three loading ports 20 disposed at a sidewall of the loader unit 13 in a manner respectively corresponding to the FOUP mounting tables 15. Each loading port 20 is coupled to one of the FOUPs 14 mounted on one of the FOUP mounting tables 15. By unloading the wafer W from the FOUP 14 mounted on the FOUP mounting table 15 via the loading port 20, the transfer arm unit 19 transfers the unloaded wafer W into and out of the first process ship 11, the second process ship 12, the orienter 16, the first IMS 17 and/or the second IMS 18.

The first IMS 17, which functions as an optical monitor, includes a mounting table 21 for mounting thereon the loaded wafer W; and an optical sensor 22 directed to the wafer W mounted on the mounting table 21 to measure a surface shape of the wafer W (for example, a film thickness of a surface layer, and a CD (Critical Dimension) value of a wiring trench or a gate electrode). The second IMS 18, which also functions as an optical monitor in the same manner as the first IMS 17, includes a mounting table 23 and an optical sensor 24, and measures the number of particles on the surface of the wafer W.

Further, the first process ship 11 includes a first process unit 25 for performing the RIE process on the wafer W; and a first load-lock unit 27 having therein a first transfer arm 26 of a link-shaped single pick type for transferring the wafer W to the first process unit 25.

The first process unit 25 includes a cylindrical processing chamber; and an upper and a lower electrode. The upper and the lower electrode are disposed in the processing chamber to be spaced from each other at a distance suitable for performing the RIE process on the wafer W. Further, an ESC 28 for chucking the wafer W by Coulomb force or the like is disposed at a top portion of the lower electrode.

In the first process unit 25, a processing gas is introduced into the chamber; and an electric field is generated between the upper and the lower electrode, so that the introduced processing gas is converted into a plasma to produce ions and radicals. Then, the RIE process is performed on the wafer W by using the ions and the radicals.

In the first process ship 11, an inside of the loader unit 13 is maintained at an atmospheric pressure, whereas an inside of the first process unit 25 is maintained at a vacuum level. Thus, the first load-lock unit 27 is configured as a vacuum antechamber having a vacuum gate valve 29 at a connection part of the first load-lock unit 27 connected to the first process unit 25, and an atmospheric gate valve 30 at a connection part of the first load-lock unit 27 connected to the loader unit 13, such that the internal pressure of the first load-lock unit 27 is controllable by the vacuum gate valve 29 and the atmospheric gate valve 30.

In the first load-lock unit 27, the first transfer arm 26 is installed approximately at a central portion thereof; a first buffer 31 is installed at a position that is located in a direction toward the first process unit 25 from the first transfer arm 26; and a second buffer 32 is installed at a position that is located in a direction toward the loader unit 13 from the first transfer arm 26. The first and the second buffer 31 and 32 are installed along a moving path of a supporting portion (a pick) 33 that supports the wafer W, wherein the supporting portion 33 is disposed at a leading end portion of the first transfer arm 26. Accordingly, by temporarily moving the wafer W on which the RIE process has been completed upward from the moving path of the supporting portion 33, the RIE processed wafer W can be easily replaced with an unprocessed wafer W (i.e., a wafer that is not yet RIE processed) in the first process unit 25.

The second process ship 12 includes a second process unit 34 for performing the COR process on the wafer W; a third process unit 36, connected to the second process unit 34 via a vacuum gate valve 35, for performing the PHT process on the wafer W; and a second load-lock unit 49 having therein a second transfer arm 37 of a link-shaped single pick type for transferring the wafer W to the second process unit 34 and the third process unit 36.

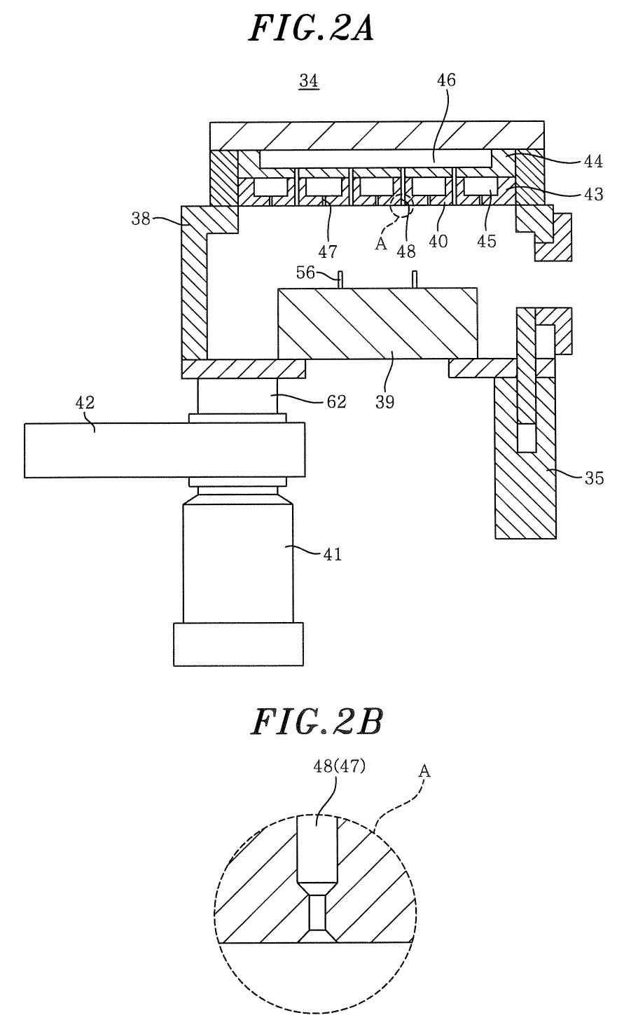

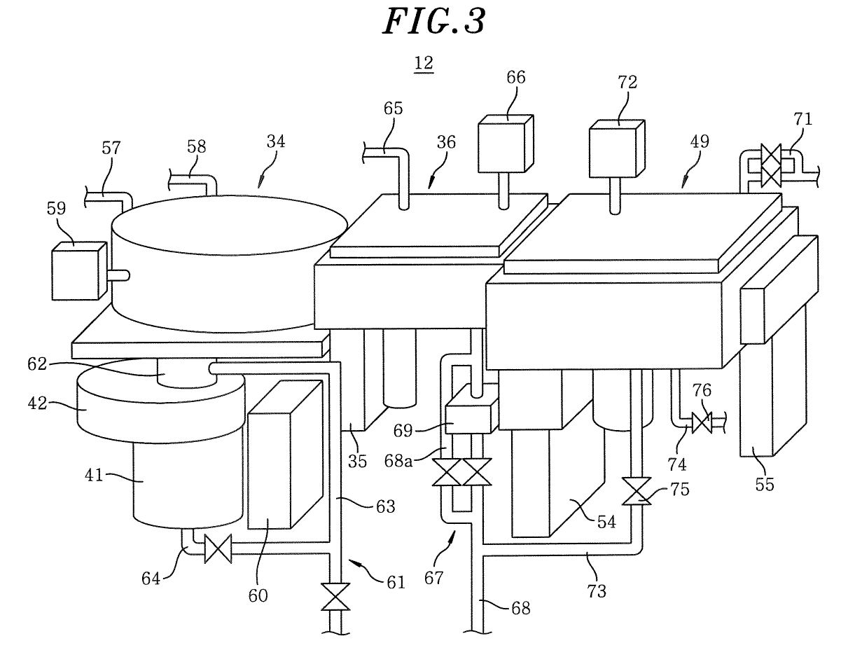

FIG. 2A is a cross sectional view of the second process unit 34 of FIG. 1, which is taken along the line II-II of FIG. 1; and FIG. 2B is an enlarged view of a portion A in FIG. 2A.

As shown in FIG. 2A, the second process unit 34 includes a cylindrical processing chamber 38; an ESC 39 serving as a mounting table of the wafer W, disposed in the processing chamber 38; a shower head 40 disposed at an upper portion of the processing chamber 38; a TMP (Turbo Molecular Pump) 41 for exhausting gas or the like from the processing chamber 38; and an APC (Automatic Pressure Control) valve 42, disposed between the processing chamber 38 and the TMP 41, serving as a variable butterfly valve which controls a pressure in the processing chamber 38.

The ESC 39 has an electrode plate (not shown) therein to which a DC voltage is applied, and adsorptively holds the wafer W by Coulomb force or Johnsen-Rahbek force generated by the DC voltage. Further, the ESC 39 has a coolant chamber (not shown) serving as a temperature controlling mechanism. A coolant of a specific temperature such as cooling water or galden solution is circulated and supplied into this coolant chamber, so that the processing temperature of the wafer W adsorptively held on the top surface of the ESC 39 can be controlled by the temperature of the coolant.

Moreover, the ESC 39 has a thermally conductive gas feeding system (not shown) to supply a thermally conductive gas (helium gas) to an entire space between the top surface of the ESC 39 and a backside of the wafer. During the COR process, the thermally conductive gas exchanges heat between the ESC 39 maintained at a desired temperature by the coolant and the wafer, thereby efficiently and evenly cooling the wafer.

Meanwhile, the ESC 39 has a plurality of pusher pins 56 serving as lift pins capable of protruding from the top surface thereof. The pusher pins 56 are accommodated in the ESC 39 when the wafer W is adsorptively held on the ESC 39. However, when the COR processed wafer W is to be unloaded from the processing chamber 38, the pusher pins 56 protrude from the top surface of the ESC 39 to lift up the wafer W.

The shower head 40 is of a two-layer structure in which a first and a second buffer chamber 45 and 46 are respectively disposed at a lower and an upper portion 43 and 44 thereof. The first and the second buffer chamber 45 and 46 communicate with the inside of the processing chamber 38 via gas holes 47 and 48, respectively. In other words, the shower head 40 is formed of two flat plates (the lower and the upper portion 43 and 44) of a laminated structure, each of which has an internal passage through which a gas supplied to the first buffer chamber 45 or the second buffer chamber 46 is introduced to the processing chamber 38.

When the COR process is performed on the wafer W, an NH₃ (ammonia) gas is supplied into the first buffer chamber 45 through an ammonia gas supply line 57 which will be described later. Then, the supplied ammonia gas is supplied into the processing chamber 38 through the gas holes 47. Meanwhile, an HF (hydrogen fluoride) gas is supplied into the second buffer chamber 46 from a hydrogen fluoride gas supply line 58 that will be described later. Thereafter, the hydrogen fluoride gas is supplied into the processing chamber 38 through the gas holes 48.

Further, the shower head 40 has therein a heater (not shown) such as a heating element. The heating element is preferably disposed in the upper portion 44 to control the temperature of the hydrogen fluoride gas in the second buffer chamber 46.

Further, as shown in FIG. 2B, each of the gas holes 47 and 48 is formed such that, at a vicinity of the chamber 38, a horizontal cross section thereof becomes larger as it gets closer to the processing chamber 38. Thus, the ammonia gas and the hydrogen fluoride gas can be efficiently diffused into the processing chamber 38. Furthermore, since each of the gas holes 47 and 48 has a vertical cross section of a narrowed neck portion, deposits generated in the processing chamber 38 can be prevented from flowing backwards to the gas holes 47 and 48, or to the first and the second buffer chamber 45 and 46. Moreover, the gas holes 47 and 48 may be of a spiral shape.

The second process unit 34 performs the COR process on the wafer W by controlling the pressure in the processing chamber 38 and a volumetric flow rate ratio of the ammonia gas to the hydrogen fluoride gas. Here, the second process unit 34 is designed such that the ammonia gas and the hydrogen fluoride gas are to be mixed first in the processing chamber 38 (a post-mix type). Thus, since the two gases are kept from being mixed until injected into the processing chamber 38, the ammonia gas and the hydrogen fluoride gas are prevented from being chemically reacted before being introduced into the processing chamber 38.

Further, in the second process unit 34, the sidewall of the processing chamber 38 has therein a heater (not shown) such as a heating element, and the ambient temperature of the processing chamber 38 is kept from being reduced. Thus, the reproducibility of the COR process can be improved. Further, the heating element embedded in the sidewall prevents by-products generated in the processing chamber 38 from being attached onto the inner sidewall by controlling the temperature of the sidewall.

Returning to FIG. 1, the third process unit 36 includes a processing chamber 50 of a shape of housing; a stage heater 51 serving as a mounting table of the wafer W disposed in the processing chamber 50; a buffer arm 52, disposed around the stage heater 51, for lifting up the wafer W mounted on the stage heater 51; and a PHT chamber lid (not shown) serving as a lid that can be freely opened and closed for isolating the inner chamber atmosphere from the outer chamber atmosphere.

The stage heater 51 is formed of aluminum having an oxidized film formed thereon, and heats the mounted wafer W to a specific temperature by using a built-in heating wire or the like. To be specific, the stage heater 51 directly heats the mounted wafer W for at least one minute to a temperature of 100 to 200° C., preferably to a temperature of about 135° C.

A sheath heater formed of silicon rubber is disposed in the PHT chamber lid. A cartridge heater (not shown) is built in the sidewall of the processing chamber 50 to control the temperature of the wall surface of the sidewall of the processing chamber 50 to be within a range from 25 to 80° C. Therefore, the by-products can be prevented from being attached onto the sidewall of the processing chamber 50, and particle generation due to the attached by-products can be prevented, so that a cleaning cycle of the processing chamber 50 can be extended. Further, the peripheral portion of the processing chamber 50 is covered by a heat shield.

Instead of the sheath heater, a UV radiation heater may be disposed as a heater for heating the wafer W from above. As the UV radiation heater, a UV lamp capable of radiating ultraviolet light whose wavelength is within a range from 190 to 400 nm can be employed.

Since the buffer arm 52 moves the COR processed wafer W temporarily upward from the moving path of the supporting portion 53 of the second transfer arm 37, the wafer W can be easily replaced in the second process unit 34 or the third process unit 36.

The third process unit 36 performs the PHT process on the wafer W by controlling a temperature of the wafer W.

The second load-lock unit 49 includes a transfer chamber 70 of a shape of housing having therein the second transfer arm 37. Further, the inside of the loader unit 13 is maintained at an atmospheric pressure, whereas the insides of the second and the third process unit 34 and 36 are maintained at a vacuum level. Thus, the second load-lock unit 49 is configured as a vacuum antechamber having a vacuum gate valve 54 at a connection part of the second load-lock unit 49 connected to the third process unit 36, and an atmospheric door valve 55 at a connection part of the second load-lock unit 49 connected to the loader unit 13, such that the internal pressure of the second load-lock unit 49 is controllable by the vacuum gate valve 54 and the atmospheric door valve 55.

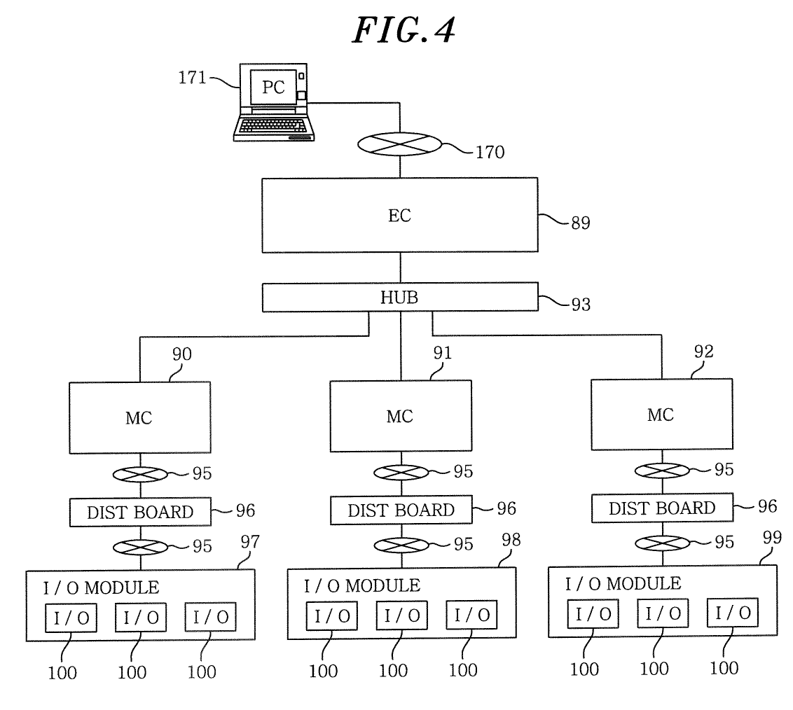

FIG. 3 is a perspective view for schematically showing a configuration of the second process ship 34 of FIG. 1.

As shown in FIG. 3, the second process unit 34 includes the ammonia gas supply line 57 for supplying the ammonia gas into the first buffer chamber 45; the hydrogen fluoride gas supply line 58 for supplying the hydrogen fluoride gas into the second buffer chamber 46; a pressure gauge 59 for measuring the pressure in the processing chamber 38; and a chiller unit 60 for supplying a coolant to a cooling system disposed in the ESC 39.

An MFC (Mass Flow Controller; not shown) is provided on the ammonia gas supply line 57, and the MFC controls a flow rate of the ammonia gas supplied into the first buffer chamber 45. Further, another MFC (not shown) is provided on the hydrogen fluoride gas supply line 58, and the MFC controls a flow rate of the hydrogen fluoride gas supplied into the second buffer chamber 46. The MFC of the ammonia gas supply line 57 and the MFC of the hydrogen fluoride gas supply line 58 cooperate to control the volumetric flow rate ratio of the ammonia gas and the hydrogen fluoride gas supplied into the processing chamber 38.

Further, a second process unit exhaust system 61 connected to a DP (Dry Pump; not shown) is disposed below the second process unit 34. The second process unit exhaust system 61 includes a gas exhaust line 63 for communicating with an exhaust duct 62 disposed between the processing chamber 38 and the APC valve 42; and a gas exhaust line 64 connected to an underside (an exhausting side) of the TMP 41, thereby exhausting gas or the like from the processing chamber 38. Further, the gas exhaust line 64 is coupled to the gas exhaust line 63 immediately before the DP.

The third process unit 36 includes a nitrogen gas supply line 65 for supplying a nitrogen (N₂) gas into the processing chamber 50; a pressure gauge 66 for measuring the pressure in the processing chamber 50; and a third process unit exhaust system 67 for exhausting the nitrogen gas or the like from the processing chamber 50.

An MFC (not shown) is provided on the nitrogen gas supply line 65 to control a flow rate of the nitrogen gas supplied to the processing chamber 50. The third process unit exhaust system 67 includes a main exhaust line 68 connected to a DP for communicating with the processing chamber 50; an APC valve 69 disposed in the main exhaust line 68; and an auxiliary exhaust line 68a branched off from the main exhaust line 68 to bypass the APC valve 69, and connected to the main exhaust line 68 immediately before the DP. The APC valve 69 controls the pressure in the processing chamber 50.

The second load-lock unit 49 includes a nitrogen gas supply line 71 for supplying a nitrogen gas into the transfer chamber 70; a pressure gauge 72 for measuring a pressure in the transfer chamber 70; a second load-lock unit exhaust system 73 for exhausting the nitrogen gas or the like from the transfer chamber 70; and an atmosphere communicating pipe 74 for opening an inside of the transfer chamber 70 to an atmosphere.

An MFC (not shown) is provided on the nitrogen gas supply line 71 to control a flow rate of the nitrogen gas supplied to the transfer chamber 70. The second load-lock unit exhaust system 73, configured with one gas exhaust line, communicates with the transfer chamber 70 and is connected to the main exhaust line 68 of the third process unit exhaust system 67 immediately before the DP. Further, the second load-lock unit exhaust system 73 and the atmosphere communicating pipe 74 have an exhaust valve 75 and a relief valve 76, respectively. The exhaust valve 75 and the relief valve 76, capable of being freely opened and closed, cooperate to control the pressure in the transfer chamber 70 to a desired pressure within a range from an atmospheric pressure to a vacuum level.

Returning to FIG. 1, the substrate processing apparatus 10 further includes a system controller for controlling operations of the first process ship 11, the second process ship 12 and the loader unit 13; and an operation panel 88 disposed on one end portion in the longitudinal direction of the loader unit 13.

The operation panel 88 includes a display configured with, e.g., an LCD (Liquid Crystal Display) to indicate a current operational state of each component of the substrate processing apparatus 10.

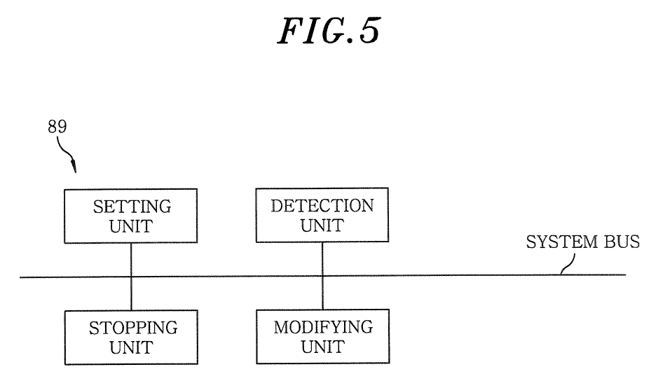

As shown in FIG. 4, the system controller includes an EC (Equipment Controller) 89; three MCs (Module Controllers) 90, 91 and 92; and a switching hub 93 for connecting the EC 89 to each MC. In the system controller, the EC 89 is connected to a PC 171 serving as a MES (Manufacturing Execution System) through a LAN (Local Area Network) 170, wherein the MES manages the manufacturing processes carried out in the entire factory where the substrate processing apparatus 10 is installed. The MES provides feedback of real time information on the processes performed in the factory to a basic operation system (not shown) by cooperating with the system controller, and performs determinations about the processes by considering, e.g., a total load of the factory.

The EC 89 is a main control unit (a master control unit) for controlling operations of the entire substrate processing apparatus 10 by controlling each MC. Further, the EC 89 includes a CPU, a RAM, an HDD and the like, and controls operations of the first process ship 11, the second process ship 12 and the loader unit 13 by transmitting control signals thereto according to processing conditions for the wafer W, i.e., a program corresponding to a recipe set by an operator or the like through the operation controller 88.

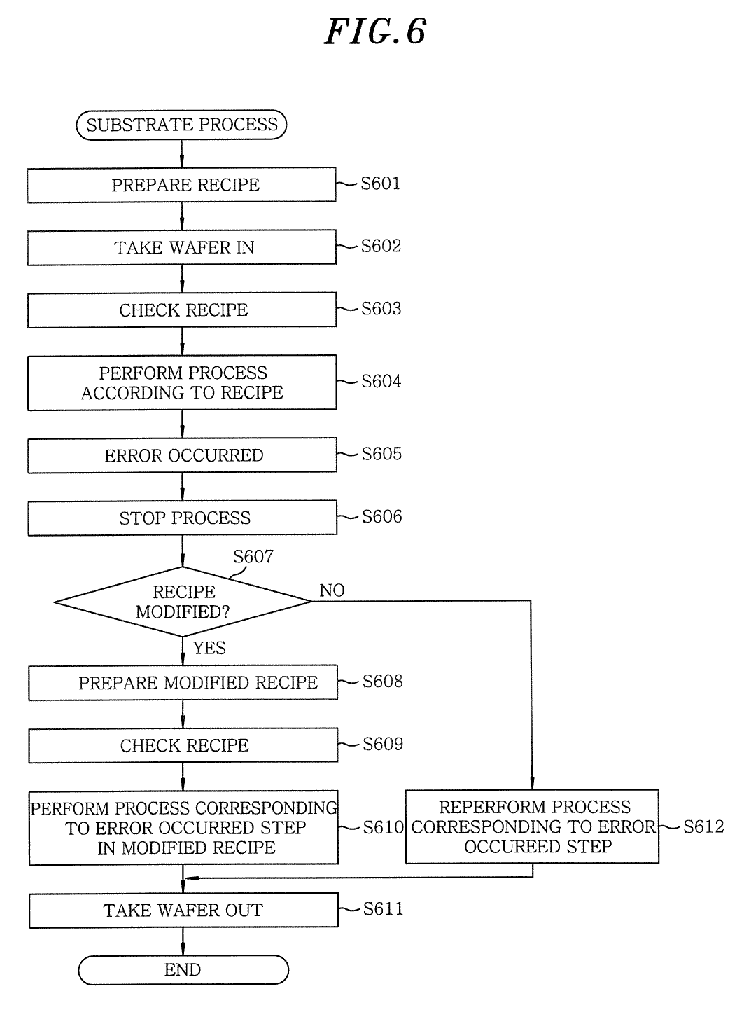

Further, as shown in FIG. 5, the EC 89 includes a setting unit for setting a recipe of the wafer W; a detection unit for detecting an abnormality of each process unit; a stopping unit for stopping the processing of the wafer W in each process unit if the detection unit detects an abnormality; a modifying unit for changing the recipe of the wafer W; and a system bus connected to each of the above-mentioned units.

Returning to FIG. 4, the switching hub 93 selectively connects the EC 89 to the respective MCs according to the control signal from the EC 89.

The MCs 90, 91 and 92 are sub-control units (slave control units) for controlling the operations of the first process ship 11, the second process ship 12 and the loader unit 13, respectively. The MCs are connected to respective I/O (Input/Output) modules 97, 98 and 99 through GHOST network 95 by using DIST (Distribution) boards 96. The GHOST network 95 is implemented by an LSI called a GHOST (General High-Speed Optimum Scalable Transceiver) mounted on an MC board of the MC. The GHOST network 95 can be connected to thirty-one I/O modules at the most. Further, in the GHOST network 95, the MCs are masters, and the I/O modules are slaves.

The I/O module 98 is formed of a plurality of I/O units 100 connected to the respective components (hereinafter, referred to as “end devices”) of the second process ship 12, and transfers control signals for the respective end devices and output signals transmitted from the respective end devices. For example, the MFC disposed on the ammonia gas supply line 57, the MFC disposed on the hydrogen fluoride gas supply line 58, the pressure gauge 59 and the APC valve 42 in the second process unit 34, the MFC disposed on the nitrogen gas supply line 65, the pressure gauge 66, the APC valve 69, the buffer arm 52 and the stage heater 51 in the third process unit 36, and the MFC disposed on the nitrogen gas supply line 71, the pressure gauge 72 and the second transfer arm 37 in the second load-lock unit 49 serve as the end devices connected to the I/O units 100 in the I/O module 98.

The configurations of the I/O modules 97 and 99 are identical to that of the I/O module 98. Further, connection relationships between the MC 90 and the I/O module 97 that controls the first process ship 11, and connection relationships between the MC 92 and the I/O module 99 that controls the loader unit 13 are identical to the above-described connection relationships between the MC 91 and the I/O module 98. Therefore, the detailed explanation thereof will be omitted.

Furthermore, the GHOST network 95 is connected to I/O boards (not shown) for controlling the input/output of digital, analog and serial signals to/from the I/O units 100.

When performing the COR process on the wafer W in the substrate processing apparatus 10, the EC 89 transmits control signals to an end device that is to be controlled through the switching hub 93, the MC 91, the GHOST network 95 and the I/O module 98 according to a program corresponding to the recipe of the COR process. In this manner, the EC 89 performs the COR process in the second process unit 34.

To be specific, the EC 89 controls the volumetric flow rate ratio of the ammonia gas to the hydrogen fluoride gas in the processing chamber 38 to be a desired value by transmitting control signals to the MFC disposed on the ammonia gas supply line 57 and the MFC disposed on the hydrogen fluoride gas supply line 58. Further, the EC 89 controls the pressure in the processing chamber 38 to be a desired level by transmitting control signals to the TMP 41 and the APC valve 42. Furthermore, at this time, the pressure gauge 59 sends data on the pressure in the processing chamber 38 to the EC 89 as an output signal; and the EC 89 determines control parameters of the MFC of the ammonia gas supply line 57, the MFC of the hydrogen fluoride gas supply line 58, the APC valve 42, and TMP 41 on the basis of the transmitted data on the pressure in the processing chamber 38.

Further, when performing the PHT process on the wafer W, the EC 89 transmits control signals to an end device to be controlled in accordance with a program corresponding to the recipe of the PHT process to thereby carry out the PHT process in the third process unit 36.

More specifically, the EC 89 controls the pressure in the processing chamber 50 to be a desired level by transmitting control signals to the MFC disposed on the nitrogen gas supply line 65 and the APC valve 69. Further, the EC 89 controls the temperature of the wafer W to be a desired level by transmitting control signals to the stage heater 51. Further, at this time, the pressure gauge 66 sends data on the pressure in the processing chamber 50 to EC 89 as an output signal; and the EC 89 determines control parameters of the APC valve 69 or the MFC of the nitrogen gas supply line 65 on the basis of the transmitted data on the pressure in the processing chamber 50.

In the system controller shown in FIG. 4, a plurality of end devices are not directly connected to the EC 89 but connected to the I/O units 100 that are respectively modularized to form I/O modules; and each of the I/O module is connected to the EC 89 through the MC and the switching hub 93. In this manner, the communications system can be simplified.

Further, the control signal transmitted by the EC 89 includes an address of the I/O unit 100 connected to the end device to be controlled and an address of the I/O module having the I/O unit 100. Thus, the switching hub 93 refers to the address of the I/O module included in the control signal; and the GHOST of the MC refers to the address of the I/O unit 100 included in the control signal. Accordingly, the switching hub 93 and the MC need not send an inquiry about a transmission source of the control signal to the CPU. In this manner, the control signal can be transferred efficiently.

In the substrate processing apparatus 10, when manufacturing electronic devices by performing the RIE process, the COR process or the PHT process on a plurality of wafers W, the operator sets a recipe buffering function to be valid by the operation panel 88. If the recipe is modified by the operator in order to cope with an error occurred during processes according to the recipe, the recipe buffering function prohibits the modified recipe from being applied to the next wafer W. Here, while performing the processes on the wafers equivalent to one lot accommodated in one FOUP 14, the EC 89 does not register a recipe input of the first process unit 25, the second process unit 34 or the third process unit 36 modified by the operator unless an error occurs as described above. Further, by controlling the MC 90 and the MC 91, the EC 89 preserves the current recipes of the first process unit 25, the second process unit 34 and the third process unit 36.

Hereinafter, the substrate processes carried out by the substrate processing apparatus in accordance with the embodiment of the present invention will be described.

The EC controls the operations of the first process ship 11, the second process ship 12 and the loader unit 13 according to the program, the input of the operator or the like, thereby performing the substrate processes. Further, although the substrate processes will be described by referring to the first process unit 25, the description can also be applied to the second process unit 34 and the third process unit 36.

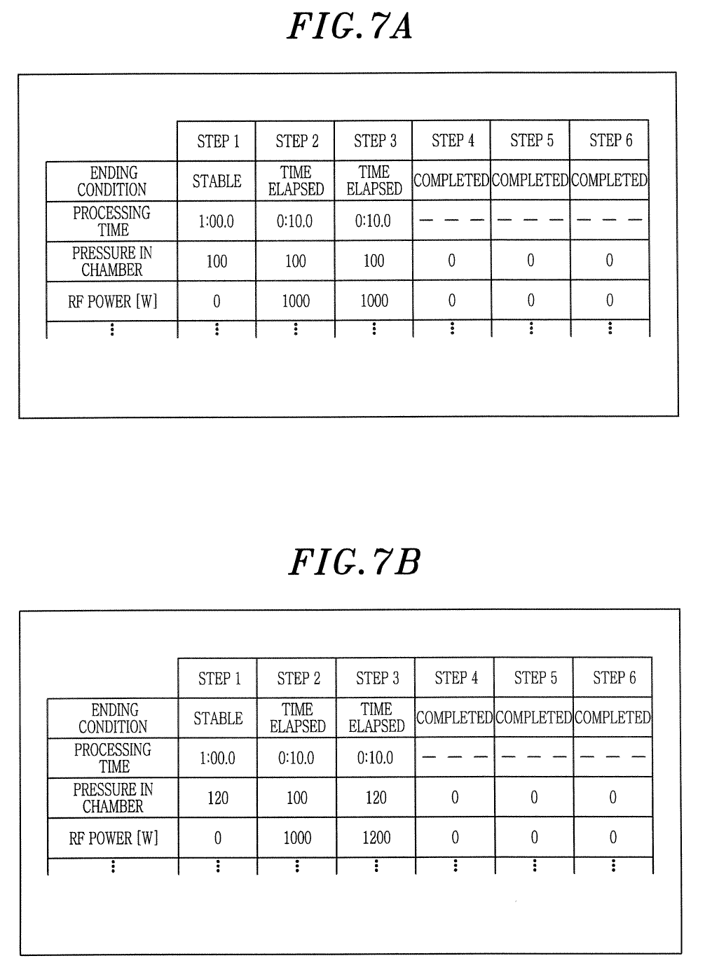

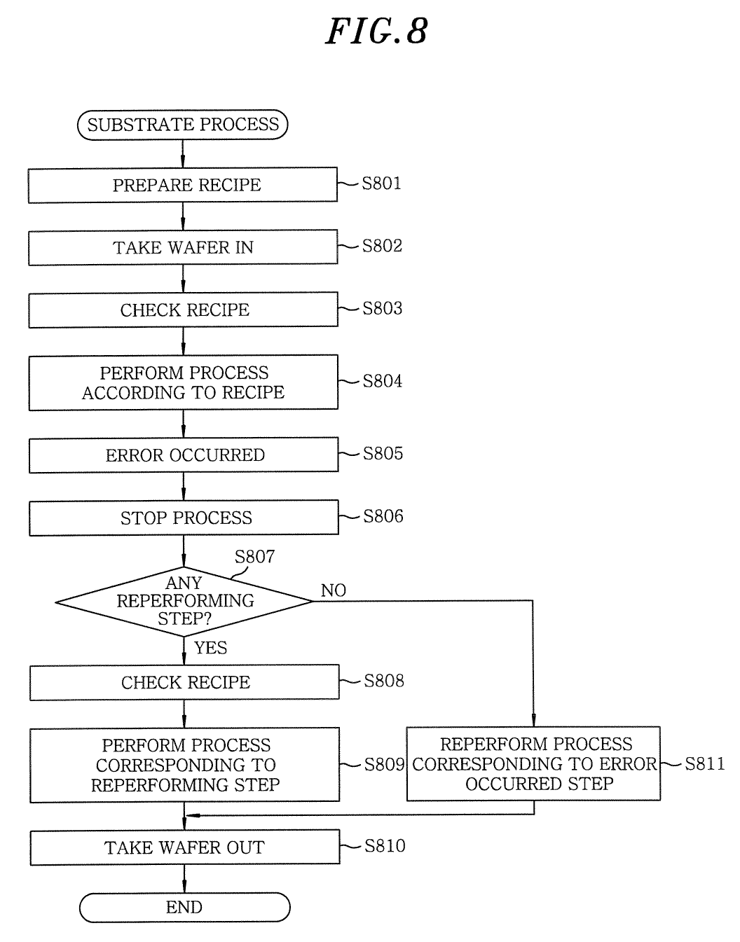

FIG. 6 is a flow chart for explaining a sequence of a first substrate process performed by the substrate processing apparatus in accordance with an embodiment of the present invention; and FIGS. 7A and 7B show a recipe edit view shown in a display of the operation panel 88.

Referring to FIG. 6, the operator inputs a recipe shown in FIG. 7A to perform the RIE process on the wafer W. The recipe illustrated in FIG. 7A represents information about the RIE processing steps, and includes data such as processing times of the RIE processing steps, wherein the RIE processing steps include a stabilization step, a first time step, a second time step and an ending step in this order.

In the stabilization step in this recipe, conditions of the chamber are arranged for performing an RF application process on the wafer W in the time steps; in the time steps, the RF application process, an RF non-application process or the like is performed on the wafer W; and in the ending step, conditions of the chamber are arranged for unloading the wafer W on which the RIE process is completely performed to the outside of the chamber, or the wafer W is unloaded to the outside of the chamber.

Further, the EC 89 sets the above-described recipe inputted by the operator as a recipe of the RIE process to be performed on the wafer W, and prepares the recipe in the first process unit 25 (setting step; step S601).

Thereafter, the wafer W is loaded into the first process unit 25 from the FOUP 14 through the loader unit 13 or the first load-lock unit 27 (step S602). Then, it is checked whether or not there may occur any problems if the steps of the recipe are performed (hereinafter, this operation will be referred to as “recipe check”; step S603). Subsequently, the RIE process corresponding to the recipe is performed on the wafer W in the order of the steps therein (step S604).

Further, in the first process unit 25, if an error is detected during the RIE process corresponding to the recipe (detecting step; step S605), the EC 89 stops the RIE process of the first process unit 25 (stopping step; step S606). In this procedure, it is assumed that the error occurred during the second time step in the recipe of FIG. 7A. At this time, the wafer W is not transferred from the first process unit 25 but is held in the first process unit 25.

Further, the EC 89 displays the recipe edit view shown in FIG. 7A on the operation panel 88. The operator can perform a recipe modification by using the recipe edit view. In this procedure, when an error occurred during a step in the recipe except for the stabilization step to thereby step the RIE process of the wafer W, if the operator modifies the recipe by performing a recipe modification except for an ending condition and a processing of the error occurred step (i.e., the step in which the error occurred) and a choice between the RF application and RF non-application in the error occurred step, the stabilization step immediately before the error occurred step is performed. Thereafter, the error occurred step is performed only for a remaining processing time at the time when the error occurs (hereinafter, referred to as “residual time”). In this case, the operator performs a recipe modification so that recipe information of the stabilization step immediately before the error occurred step corresponds to modified recipe information of the error occurred step (see FIG. 7B).

Thereafter, the EC 89 determines whether or not a recipe modification is performed by the operator as described above (step S607). If a recipe modification is performed, EC 89 modifies the recipe according to the recipe modification, and prepares the modified recipe in the first process unit 25 (modifying step; step S608); and then performs the recipe check of the modified recipe (step S609). Thereafter, the RIE process corresponding to the error occurred step in the modified recipe is carried out on the wafer W (step S610).

In the process of step S610, if the recipe is modified except for the ending condition and the processing time of the error occurred step, and the choice between the RF application and the RF non-application in the error occurred step, the stabilization step immediately before the error occurred step is performed. Thereafter, the error occurred step is performed only for the residual time.

On the other hand, if the recipe information about the ending condition or the processing time of the error occurred step, the stabilization step immediately before the error occurred step is performed, and then the error occurred step is carried out. However, as an exception, in case the error occurred step is modified to the stabilization step, the error occurred step is performed without performing the stabilization step immediately before the error occurred step. Further, also in case the error occurred step is modified to the ending step, the modified recipe is reperformed from the first step thereof.

Furthermore, also in case the recipe is modified such that the RF application is modified to the RF non-application or vice versa, the error occurred step is performed without performing the stabilization step immediately before the error occurred step.

Further, after step S604, if an additional recipe modification is performed by the operator to modify another recipe information, the EC 89 modifies the recipe according to the additional recipe modification by the operator, and the modified recipe is prepared in the first process unit 25. In this case, the modified recipe is performed from the first step thereof in step S607.

Based on a result of the determination in step S607, if no recipe modification is performed by the operator, the RIE process corresponding to the error occurred step is reperformed on the wafer W (step S612).

In the procedure of step S612, unless the error occurred step is a stabilization step, the stabilization step immediately before the error occurred step is performed, and then the error occurred step is performed for the residual time. However, if the error occurred step is a stabilization step, the stabilization step immediately before the error occurred step is not performed.

The wafer W that has been RIE processed in step S610 or S612 is unloaded from the first process unit 25 (step S611), thereby finishing the process.

According to the first substrate process shown in FIG. 6, if the RIE process in the first process unit 25 is stopped (step S606), and if a recipe modification is performed by the operator (YES in step S607), the EC modifies the recipe according to the recipe modification, and the modified recipe is prepared in the first process unit 25 (step S608). Thereafter, the RIE process corresponding to the error occurred step in the modified recipe is carried out on the wafer W (step S610). Therefore, since the processing conditions for the unfinished wafer can be modified as desired, an optimal process for the unfinished wafer can be reperformed without unloading the unfinished wafer from the inside of the processing chamber.

Further, in this process, if the recipe buffering function is set to be valid, the modified recipe is not applied to the next wafer W. In contrast, if the recipe buffering function is set to be invalid, the modified recipe is applied to the next wafer W. However, as an exception, although the recipe buffering function is set to be invalid, if an additional recipe modification is performed by the operator to modify another recipe information so that the EC 89 modifies the recipe according to the additional recipe modification, the modified recipe is not applied to the next wafer W.

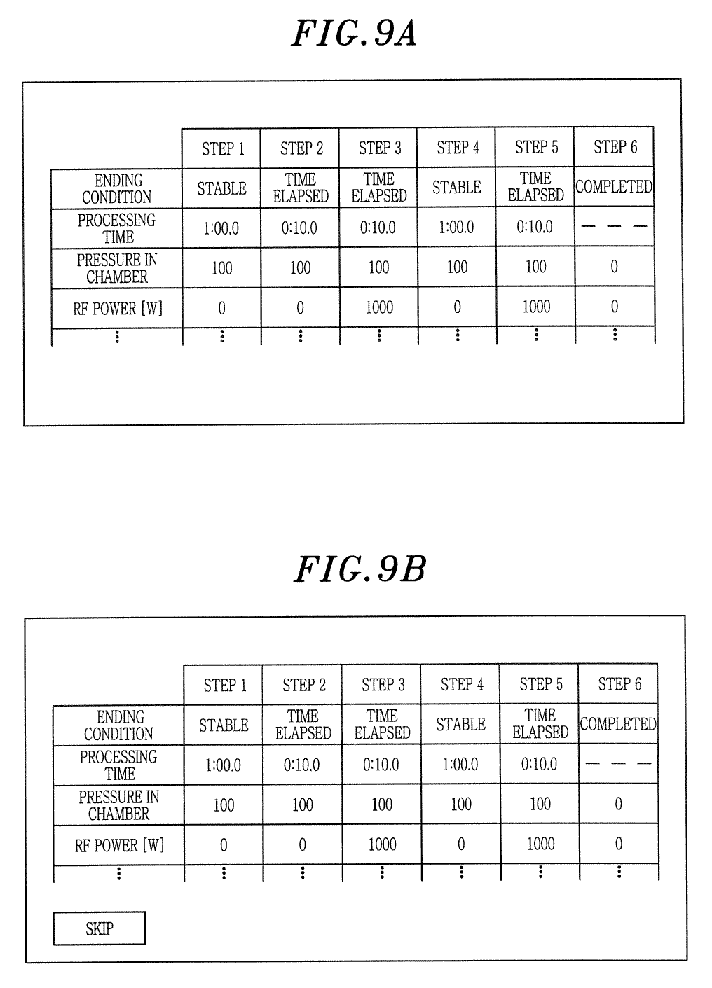

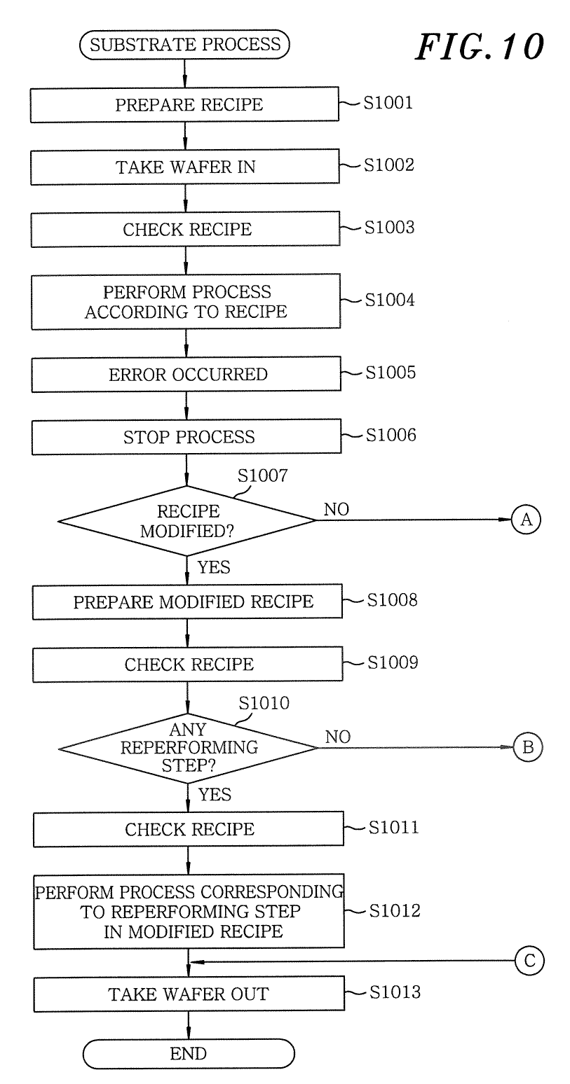

FIG. 8 is a flow chart for explaining a sequence of a second substrate process performed by the substrate processing apparatus in accordance with an embodiment of the present invention; and FIGS. 9A and 9B depict a recipe edit view shown in the display of the operation panel 88.

Referring to FIG. 8, the operator inputs a recipe shown in FIG. 9A to perform the RIE process on the wafer W. The recipe illustrated in FIG. 9A represents information about the RIE processing steps, and includes data such as processing times of the RIE processing steps, wherein the RIE processing steps include a stabilization step, a first time step, a second time step, a second stabilization step, a third time step and an ending step in this order.

Further, the EC 89 sets the above-described recipe inputted by the operator as a recipe of the RIE process to be performed on the wafer W, and prepares the recipe in the first process unit 25 (setting step; step S801).

Then, after the wafer W is loaded into the first process unit 25 from the FOUP 14 through the loader unit 13 or the first load-lock unit 27 (step S802), the recipe check is performed (step S803); and then the RIE process corresponding to the recipe is performed on the wafer W sequentially from its first step (step S804).

Thereafter, in the first process unit 25, if an error is detected while performing the RIE process corresponding to the recipe (detecting step; step S805), the EC 89 stops the RIE process of the first process unit 25 (stopping step; step S806). At this time, the wafer W is not transferred from the first process unit 25 but is held in the first process unit 25. Further, the EC 89 displays the recipe edit view shown in FIG. 9B on the operation panel 88. This recipe edit view has a “skip” button. By pressing the “skip” button, the operator can select the step of reperforming the process of the wafer W on which the RIE processing has been stopped to be performed.

In this process, if the error occurred step is a time step (e.g., step 3) in which an RF application is performed, the error occurred step (step 3) and the next step (step 4) of the error occurred step can be set to be reperformed by the operator.

Further, if the error occurred step is a stabilization step (e.g., step 1), only the error occurred step (step 1) can be set to be reperformed by the operator.

Furthermore, if the error occurred step is a time step (e.g., step 2) in which an RF application is not performed, only the error occurred step (step 2) can be set to be reperformed by the operator.

Thereafter, the EC 89 determines whether or not there is a step that has been set to be reperformed by the operator as described above (hereinafter, referred to as “reperforming step”) (step S807). If there is a reperforming step, EC 89 performs the recipe check on steps to be performed thereafter (step S808), and then performs on the RIE process corresponding to the reperforming step the wafer W (modifying step; step S809).

In the procedure of step S809, unless the reperforming step is a stabilization step, the stabilization step immediately before the reperforming step is performed, and then the reperforming step is carried out. On the contrary, if the reperforming step is a stabilization step, the reperforming step is performed without carrying out the stabilization step immediately before the reperforming step.

Based on a result of the determination in step S807, if there is no step that is set to be reperformed by the operator, the RIE process corresponding to the error occurred step is reperformed on the wafer W (step S811).

In the procedure of step S811, if the error occurred step is not a stabilization step, the stabilization step immediately before the error occurred step is performed, and then the error occurred step is performed for the residual time. In contrast, if the error occurred step is a stabilization step, the error occurred step is performed for the residual time without carrying out the stabilization step immediately before the error occurred step.

The wafer W that has been RIE processed in step S809 or step S811 is unloaded from the first process unit 25 (step S810), thereby finishing the process.

According to the second substrate process shown in FIG. 8, if the RIE process in the first process unit 25 is stopped (step S806), and if there is a step that is set to be reperformed by the operator (YES in step S807), the EC performs the RIE process corresponding to the reperforming step on the wafer W (step S809). Therefore, the processing conditions for the unfinished wafer can be modified as desired, so that an optimal process for the unfinished wafer can be reperformed without unloading the unfinished wafer from the inside of the processing chamber.

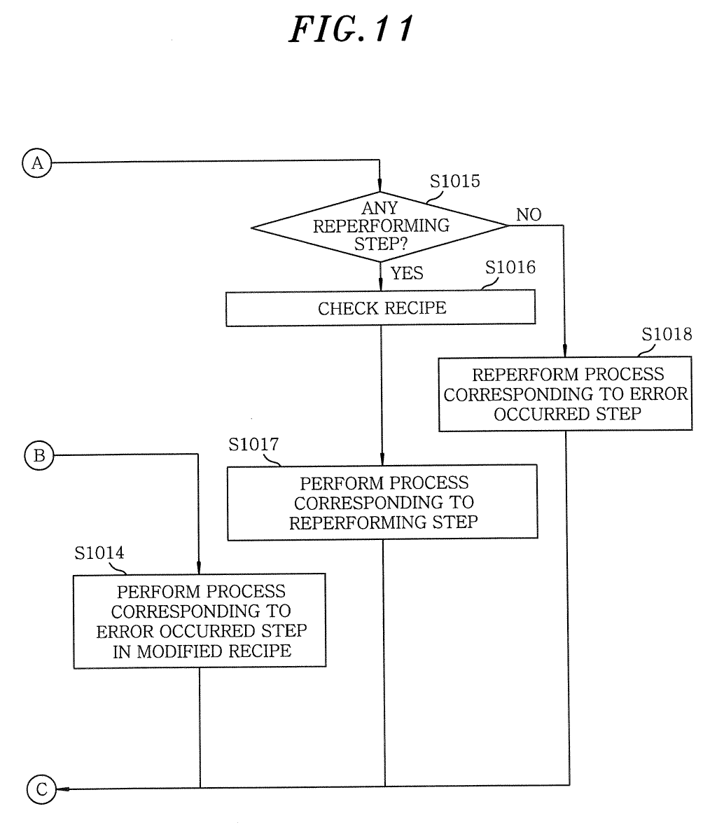

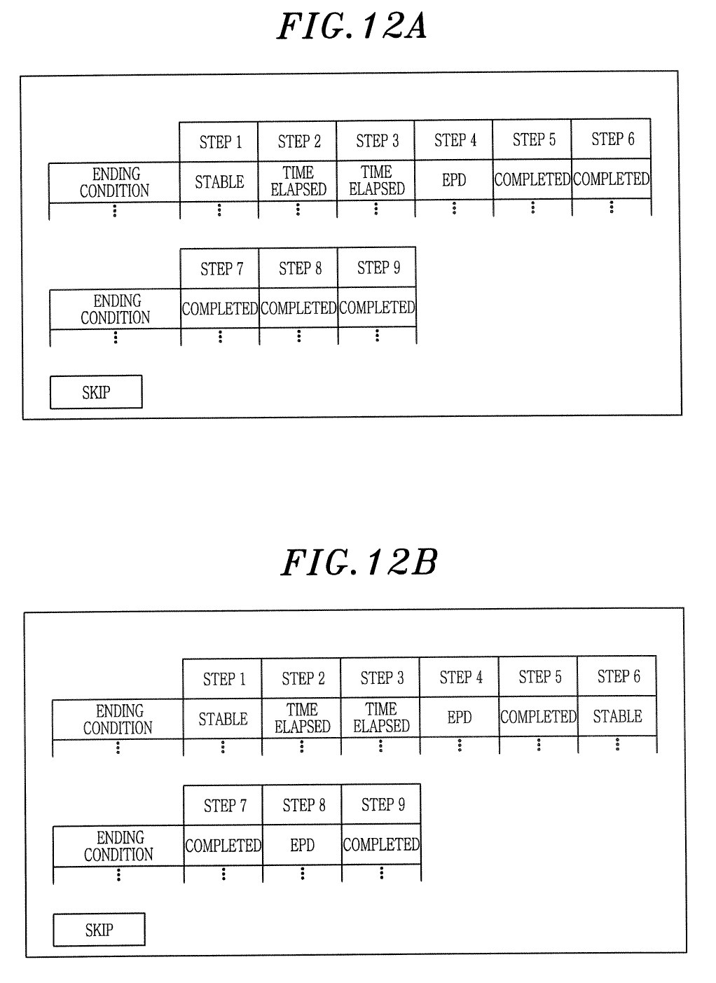

FIGS. 10 and 11 are flow charts for explaining a sequence of the third substrate process performed by the substrate processing apparatus in accordance with an embodiment of the present invention; and FIGS. 12A and 12B show a recipe edit view shown in the display of the operation panel 88.

Referring to FIGS. 10 and 11, the operator inputs a recipe shown in FIG. 12A to perform the RIE process on the wafer W. The recipe illustrated in FIG. 12A represents information about the RIE processing steps, and includes data such as processing times of the RIE processing steps, wherein the RIE processing steps include a stabilization step, a first time step, a second time step, an EPD step and an ending step in this order. In the EPD step in this recipe, an end point of the RIE process is detected.

Then, the EC 89 sets the above-described recipe inputted by the operator as a recipe of the RIE process performed on the wafer W and develops the recipe to the first process unit 25 (setting step; step S1001).

Sequentially, after the wafer W is loaded into the first process unit 25 from the FOUP 14 through the loader unit 13 or the first load-lock unit 27 (step S1002), the recipe check is performed (step S1003); and then the RIE process corresponding to the recipe is performed on the wafer W sequentially from its first step (step S1004).

Thereafter, in the first process unit 25, if an error is detected while executing the RIE process corresponding to the recipe (detecting step; step S1005), the EC 89 stops the RIE process of the first process unit 25 (stopping step; step S1006). Let us assume in this process that the error occurred in the second time step in the recipe of FIG. 12A. At this time, the wafer W is not transferred from the first process unit 25, but is held in the first process unit 25. Further, the EC 89 displays the recipe edit view shown in FIG. 12A on the operation panel 88. By using the recipe edit view, the operator can perform a recipe modification as shown in FIG. 12B for example. In addition, the recipe edit view has a “skip” button. By pressing the “skip” button, the operator can select the step of reperforming the process of the wafer W on which the RIE processing has been stopped to be performed.

Subsequently, the EC determines whether or not a recipe modification is performed by the operator as described above (step S1007). If a recipe modification is performed, the EC 89 modifies the recipe according to the recipe modification, and prepares the modified recipe in the first process unit 25 (modifying step; step S1008). Thereafter, the EC 89 performs the recipe check of the modified recipe (step S1009). Further, the EC 89 displays the recipe edit view shown in FIG. 12B on the operation panel 88. This recipe edit view also has a “skip” button. By pressing the “skip” button, the operator can select the step of reperforming the process of the wafer W on which the RIE processing has been stopped to be performed.

In this process, an error occurred step (step 3), the next step (step 4) of the error occurred step and the next step (step 6) of the ending step (step 5) can be set to be reperformed by the operator.

Then, the EC 89 determines whether or not there is any reperforming step set by the operator (step S1010). If there is a reperforming step, the EC 89 performs the recipe check of the step to be performed thereafter (step S1011), and then executes the RIE process corresponding to the reperforming step on the wafer W (modifying step, step S1012).

In the procedure of step S1012, unless the reperforming step is a stabilization step, the stabilization step immediately before the reperforming step is performed, and then the reperforming step is carried out. On the contrary, if the reperforming step is a stabilization step, the reperforming step is performed without carrying out the stabilization step immediately before the reperforming step.

Based on a result of the determination in step S1010, if there is not any reperforming step set by the operator, the RIE process corresponding to the error occurred step in the modified recipe is performed on the wafer W (step S1014).

However, based on a result of the determination in step S1007, if there is no recipe modification by the operator, the EC 89 determines whether there is any reperforming step set by the operator as described above (step S1015). Then, if there is a reperforming step, the EC 89 performs the recipe check of the step to be performed thereafter (step S1016), and then executes the RIE process corresponding to the reperforming step on the wafer W (modifying step; step S1017)

Based on a result of the determination in step S1015, if there is not any reperforming set by the operator, the RIE process corresponding to the error occurred step is reperformed on the wafer W (step S1018).

The RIE processed wafer W in step S1012, S1014, S1017 or S1018 is unloaded from the first process unit 25 (step S1013), thereby finishing the process.

According to the third substrate process shown in FIGS. 10 and 11, if the RIE process in the first process unit 25 is stopped (step S1006), and if there is a recipe modification by the operator (YES in step S1007), the EC 89 modifies the recipe according to the recipe modification; and prepares the modified recipe in the first process unit 25 (step S1008). Thereafter, if there is a reperforming step by the operator (YES in step S1010), the RIE process corresponding to the reperforming step in the modified recipe is carried out on the wafer W (step S1012). Therefore, the processing conditions for the unfinished wafer can be modified as desired, so that an optimal process for the unfinished wafer can be reperformed without unloading the unfinished wafer from the inside of the processing chamber.

Further, in this process, if the recipe buffering function is set to be valid, the modified recipe is not applied to the next wafer W. In contrast, if the recipe buffering function is set to be invalid, the modified recipe is applied to the next wafer W. However, as an exception, although the recipe buffering function is set to be invalid, if an additional recipe modification is performed by the operator to modify another recipe information so that the EC 89 modifies the recipe according to the additional recipe modification, the modified recipe is not applied to the next wafer W.

In the present embodiment of the invention, in case of reperforming the RIE process on the wafer W on which the RIE process has been stopped to be performed, the operator can check whether or not the recipe of the wafer is modified by checking information about a process log of the wafer W. The process log contains information about whether or not the recipe is modified by the operator following a stoppage of the RIE process on the wafer W.

In the substrate processing apparatus in accordance with the above-described embodiment of the present invention, the two process ships have been described to be of different structures. However, it is also possible that the two process ships are of a same structure. For example, both of the process ships may be of a structure for performing an RIE process on the wafer W.

Further, in the substrate processing apparatus in accordance with the above-described embodiment of the present invention, a target substrate to be processed by an RIE process or the like is not limited to a semiconductor wafer for an electronic device. Instead, various kinds of substrates such as a photo mask, a CD substrate, a print substrate or a substrate used for, e.g., an LCD (Liquid Crystal display), a FPD (Flat Panel Display) or the like can also be used as the target substrate.

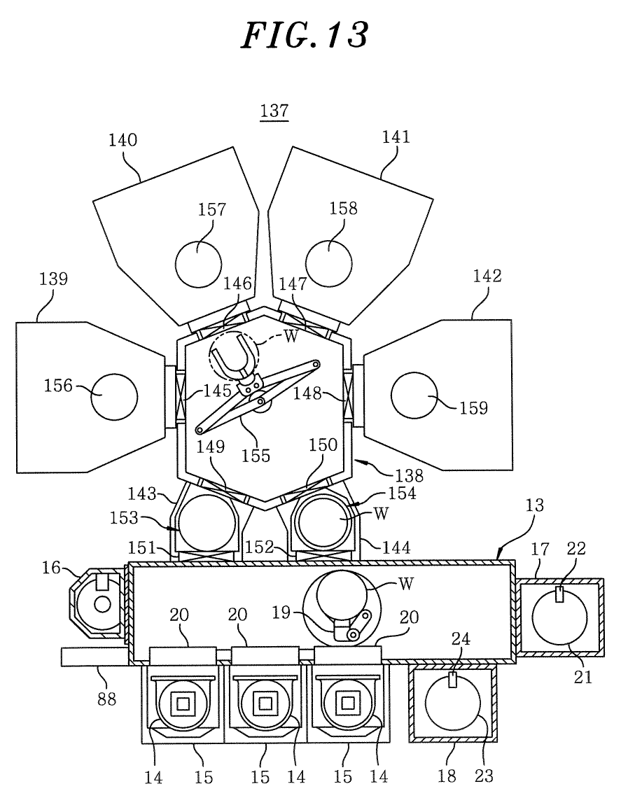

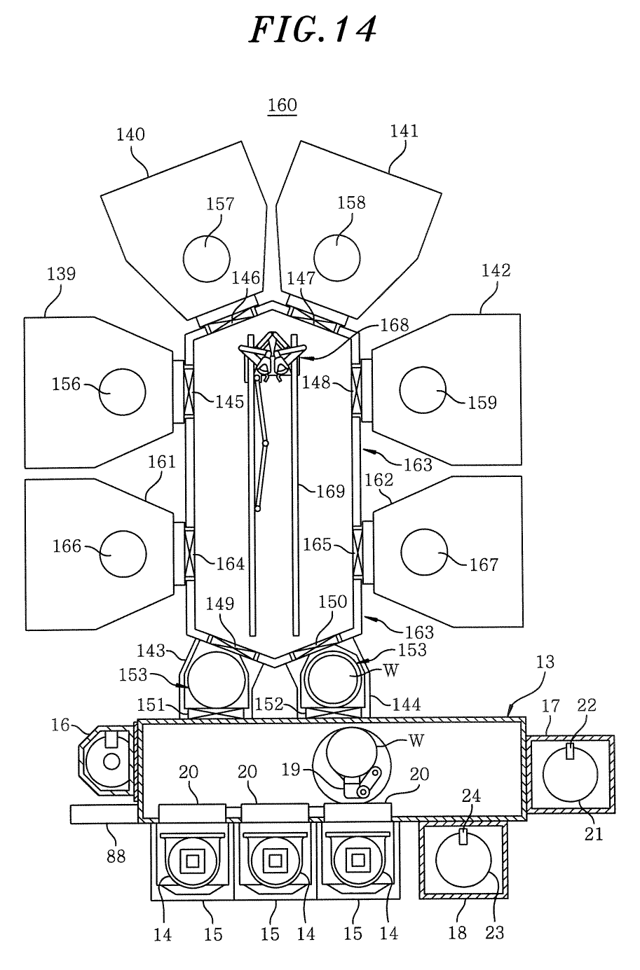

Further, the substrate processing apparatus in accordance with the above-described embodiment of the present invention is not limited to a parallel type substrate processing apparatus having two process ships disposed parallel to each other as shown in FIG. 1. Instead, the present invention can also be applied to a substrate processing apparatus in which a plurality of process units serving as vacuum processing units for performing specific processes on the wafer W are disposed radially as shown in FIGS. 13 and 14.

FIG. 13 is a plan view for schematically showing a configuration of a substrate processing apparatus in accordance with a first modified example of the embodiment of the present invention. As shown in FIG. 13, like parts identical to those of the substrate processing apparatus 10 in FIG. 1 are given like reference numerals, and description thereof will be omitted.

As shown in FIG. 13, a substrate processing apparatus 137 includes a transfer unit 138 that is of a hexagonal shape when views from a plane; four process units 139 to 142 arranged radially around the transfer unit 138; a loader unit 13; and two load-lock units 143 and 144 disposed between the transfer unit 138 and the loader unit 13 for connecting the transfer unit 138 to the loader unit 13.

Pressures in the transfer unit 138 and the process unit 139 to 142 are maintained at a vacuum level, and the transfer unit 138 is connected to the process units 139 to 142 via vacuum gate valves 145 to 148, respectively.

In the substrate processing apparatus 137, a pressure in the loader unit 13 is maintained at an atmospheric level, whereas a pressure in the transfer unit 138 is maintained at a vacuum level. On this account, the load-lock units 143 and 144 are configured as vacuum antechambers whose internal pressures are controllable by vacuum gate valves 149 and 150, respectively, together with atmospheric door valves 151 and 152, respectively. Here, the vacuum gate valves 149 and 150 are disposed at connection parts of the transfer unit 138 that is connected to the load-lock unit 143 and the load-lock unit 144, respectively. Further, the load-lock units 143 and 144 have wafer mounting tables 153 and 154, respectively, for temporarily supporting a wafer W transferred between the loader unit 13 and the transfer unit 138.

The transfer unit 138 has a frog-leg type transfer arm 155 disposed therein, which can be freely extended, retracted and rotated. The transfer arm 155 transfers the wafer W between the process units 139 to 142 and the load-lock units 143 and 144.

The process units 139 to 142 have mounting tables 156 to 159, respectively, for mounting thereon the wafer W to be processed. Herein, the configuration of each of the process units 139 and 140 is same as that of the first process unit 25 in the substrate processing apparatus 10. Further, the process unit 141 is of the same configuration as that of the second process unit 34, and the configuration of the process unit 142 is of the same configuration as that of the third process unit 36.

Further, the operation of each component in the substrate processing apparatus 137 is controlled by a system controller that is of the same configuration as that of the system controller in the substrate processing apparatus 10.

FIG. 14 is a plan view for schematically illustrating a configuration of a substrate processing apparatus in accordance with a second modified example of the embodiment of the present invention. As shown therein, like parts identical to those of the substrate processing apparatus 10 shown in FIG. 1 or the substrate processing apparatus 137 shown in FIG. 13 are given like reference numerals, and description thereof will be omitted.

As shown in FIG. 14, the substrate processing apparatus 160 further includes two process units 161 and 162 in addition to the components of the substrate processing apparatus 137 shown in FIG. 13. Further, the substrate processing apparatus 160 includes a transfer unit 163 instead of the transfer unit 138 in the substrate processing apparatus 137, wherein the transfer unit 163 is a shape different from that of the transfer unit 138. The process units 161 and 162 are coupled to the transfer unit 163 through vacuum gate valves 164 and 165, and include mounting tables 166 and 167, respectively, for mounting therein the wafer W. The process unit 161 has of the same configuration as that of the first process unit 25, and the configuration of the process unit 162 is same as that of the second process unit 34.

Further, the transfer unit 163 is provided with a transfer arm unit 168 formed of two scalar arm type transfer arms. The transfer arm unit 168 is moved along a guide rail 169 disposed in the transfer unit 163, and transfers the wafer W between the process units 139 to 142, 161 and 162 and the load-lock unit 143 and 144.

Furthermore, the operation of each component of the substrate processing apparatus 160 is controlled by a system controller that is of the same configuration as that of the system controller in the substrate processing apparatus 10.

The object of the present invention can also be achieved by providing the EC 89 with a storage medium for storing therein software program codes for executing the functions of the above-described embodiments, and having a computer (or a CPU, MPU or the like) in the EC 89 read and execute the program codes stored in the storage medium.

In this case, it is the program codes read from the storage medium that implements the functions of the above-described embodiments. Therefore, the program codes and the storage medium for storing the program codes therein should be regarded as aspects of the present invention.

Further, as the storage medium for storing therein the program codes, a floppy (registered trademark) disc, a hard disc, a magneto-optical disc, an optical disc such as a CD-ROM, a CD-R, a CD-RW, a DVD-ROM, a DVD-RAM, a DVD-RW or a DVD+RW, a magnetic tape, a nonvolatile memory card and a ROM may be employed. Furthermore, the program codes may be downloaded through the network.

In the above description, the computer reads and executes the program codes to implement the functions of the above-described embodiments. However, it is also possible to implement the functions of the above-described embodiments by having an OS (operating system) or the like that is operated for the computer execute the entire or a part of actual processes based on instructions of the program codes.

Further, it is also possible to implement the functions of the above-described embodiments by storing the program code into a memory in a function extension board installed in the computer or in a function extension unit connected to the computer, and having a CPU or the like installed in the function extension board or the function extension unit execute the entire or a part of actual processes based on instructions of the program codes.

Furthermore, the form of the above-mentioned program codes may be an object code, a program code executed by an interpreter, script data provided to an OS, or the like.

While the invention has been shown and described with respect to the embodiments, it will be understood by those skilled in the art that various changes and modification may be made without departing from the scope of the invention as defined in the following claims.

What is claimed is:

1. A substrate processing apparatus, comprising:
a setting unit for setting substrate processing conditions for a substrate in a substrate processing unit for performing a process on the substrate;
a detection unit for detecting an abnormality of the substrate processing unit while the substrate processing unit performs the process on the substrate under the substrate processing conditions;
a stopping unit for stopping the process on the substrate of the substrate processing unit if the abnormality is detected; and
a modifying unit for modifying the substrate processing conditions for a substrate on which the process is stopped to be performed by the stopping unit.

2. The substrate processing apparatus of claim 1, wherein the modifying unit modifies the substrate processing conditions by revising the substrate processing conditions.

3. The substrate processing apparatus of claim 1, wherein the substrate processing conditions include a plurality of processing conditions, and the modifying unit modifies the substrate processing conditions by selecting one or more processing conditions among the plurality of processing conditions.

4. The substrate processing apparatus of claim 2, wherein the substrate processing conditions include a plurality of processing conditions, and the modifying unit modifies the substrate processing conditions by selecting one or more processing conditions among the plurality of processing conditions.

5. A method for modifying substrate processing conditions, comprising the steps of:
setting substrate processing conditions for a substrate in a substrate processing unit for performing a process on the substrate;
detecting an abnormality of the substrate processing unit while the substrate processing unit performs the process on the substrate under the substrate processing conditions;
stopping the process of the substrate processing unit on the substrate if the abnormality is detected; and
modifying the substrate processing conditions for a substrate on which the process is stopped to be performed in the stopping step.

6. The method of claim 5, wherein, in the modifying step, the processing conditions are modified by revising the processing conditions.

7. The method of claim 5, wherein the substrate processing conditions include a plurality of processing conditions, and, in the modifying step, the substrate processing conditions are modified by selecting one or more processing conditions among the plurality of the processing conditions.

8. The method of claim 6, wherein the substrate processing conditions include a plurality of processing conditions, and, in the modifying step, the substrate processing conditions are modified by selecting processing conditions among the plurality of the processing conditions.

9. A computer readable storage medium for storing therein a program executable on a computer,
wherein the program includes:
a setting module for setting substrate processing conditions for a substrate in a substrate processing unit for performing a process on the substrate;
a detection module for detecting an abnormality of the substrate processing unit while the substrate processing unit performs the process on the substrate under the substrate processing conditions;
a stopping module for stopping the process of the substrate processing apparatus on the substrate if the abnormality is detected; and
a modifying module for modifying the substrate processing conditions for a substrate on which the process is stopped to be performed by the stopping module.
